(19) United States
(12) Patent Application Publication
(10) Pub. No.: US 2008/0170723 A1
(43) Pub. Date: Jul. 17, 2008

(54) Audio Reproducing Apparatus and Method, and Computer Program

(75) Inventors: Kei Sakagami, Saitama (JP); Shintaro Hosoi, Saitama (JP)

Correspondence Address: YOUNG & THOMPSON, 745 South 23rd Street, Suite 210, Arlington, VA, 22202, US

(73) Assignee: PIONEER CORPORATION, Tokyo (JP)

(21) Appl. No.: 11/885,547

(22) PCT Filed: Mar. 3, 2006
(86) PCT No.: PCT/JP06/04060

§ 371 Date: Oct. 22, 2007

(30) Foreign Application Priority Data
Mar. 4, 2005 (JP) 2005-061576

(51) Int. Cl. H03G 5/00

(52) U.S. Cl. 381/103

(57) ABSTRACT

An audio reproducing device (100) includes: (i) signal level detection means (102) for detecting a signal level of an audio signal; (ii) sound pressure adjusting means (104) for changing the sound pressure level indicating the amplification ratio of the audio signal; (iii) frequency characteristic correction means (106) for correcting the frequency characteristic of the audio signal according to a correction amount; and (iv) control means (103) for deciding the correction amount according to the signal level and the sound pressure level and successively controlling the frequency characteristic correction means to perform correction according to the decided correction amount.

### TECHNICAL FIELD

The present invention relates to an audio reproducing apparatus and method (or audio reproduction system) which performs signal processing on an audio signal, and a computer program for signal processing.

### BACKGROUND ART

Sound has a frequency band in which a human being can sensitively feel a change in sound volume (or sound pressure level) and a frequency band in which the human being cannot do so. For example, if the sound volume (or sound pressure level) is changed around a frequency band of 1 kHz, a human being can sensitively feel the change.

Thus, lately, in an audio reproduction apparatus (or audio system) for enjoying music or a movie recorded on a high-density recording medium, such as a DVD, so-called loudness control (or hearing correction) is performed by a correcting device, such as an equalizer, for correcting the sound pressure level in the frequency band in which a human being can sensitively feel a change in sound volume (or sound pressure level) and the frequency band in which the human being cannot do so. If the sound pressure level is attenuated or boosted by turning on or off the equalizer, it is possible to significantly change the sound volume on hearing.

In the audio reproducing apparatus including the equalizer or the like, for example, if a user adjusts the sound volume (or sound pressure level) of a main volume or the like, amplification factors of a plurality of preamplifiers are simultaneously changed under gain control by an electronic volume integrated circuit or an ASP (Audio Signal Processor) on the basis of a value set by a sound volume setting device.

Then, in the preamplifier, the loudness control is performed on the basis of the set value set on the sound volume setting device. Specifically, if the set value of the sound volume is small, the frequency characteristic of a sound volume (or sound pressure level) is corrected to increase the amplification factor of the preamplifier in a low audio range and a high audio range, compared with a middle audio range. Here, the “frequency characteristic” in the present invention is transition in level (or extent) of various signals, such as an audio signal, with the frequency as a parameter. Thus, the sound volume (or sound pressure level) on hearing, which is outputted from a speaker, is increased, i.e., boosted in the low audio range and the high audio range. More specifically, because the preamplifier performs the aforementioned loudness control, the preamplifier is provided with, for example, a signal processing circuit for loudness control (hereinafter referred to as a “loudness control circuit”) with a filter.

FIG. 12 shows gain transition with the frequency as a parameter, i.e. the frequency characteristic of the gain. In FIG. 12, the horizontal axis indicates frequency, and the vertical axis indicates the gain of the loudness control circuit. Specifically, the frequency characteristic of the gain on the vertical axis is based on the gain when the set value of the main volume has a maximum value, i.e. 0 (dB: decibel). Incidentally, in the present invention, the reference value of the unit (dB: decibel) is individually and specifically determined depending on the type of the value, on an experimental, experiential, theoretical, or simulation basis or the like.

As shown in FIG. 12, a curve located on the top shows the frequency characteristic of the gain when the set value of the main volume is large, i.e. when an average sound volume is large. On the other hand, a curve located on the bottom shows the frequency characteristic of the gain when the set value of the main volume is small, i.e. when the average sound volume is small. Moreover, two curves located in the middle portion show the frequency characteristics of the gains when the set value of the main volume is relatively moderate.

Therefore, the followings can be seen from FIG. 12: (i) if the set value of the main volume is set large, the sound volume (or sound pressure level) on hearing, which is outputted from the speaker, is large as a whole, and the curve which shows the frequency characteristic of the gain is almost flat with respect to the frequency. On the other hand, (ii) if the set value of the main volume is set small, the sound volume (or sound pressure level) on hearing, which is outputted from the speaker, is generally small as a whole, but the curve which shows the frequency characteristic of the gain has a minimum value in the vicinity of a frequency band of 1 to 2 (kHz) and the gain value is relatively large in a frequency band which is lower and higher than the frequency band of 1 to 2 (kHz).

In particular, a patent document 1 or the like discloses an audio reproducing apparatus which enhances the aforementioned loudness control and which makes the amplification factor larger in a frequency which is smaller than a predetermined frequency as the set value of the main volume gets smaller, when correcting the frequency characteristic of the amplification factor of the preamplifier. Therefore, for example, it is possible to inhibit that the sound pressure level on hearing, which is outputted from the speaker, is excessively boosted to thereby deteriorate sound quality if the set value of the sound volume is small.
Patent document 1: Japanese Patent Application Laid Open NO. 2003-158800
Patent document 2: Japanese Patent Application Laid Open NO. 2003-274488
Patent document 3: Japanese Patent Application Laid Open NO. Hei 9-182197
Patent document 4: Japanese Patent Application Laid Open NO. Hei 11-136790

### DISCLOSURE OF INVENTION

### Subject to be Solved by the Invention

However, for example, the audio reproducing apparatus disclosed in the aforementioned patent document 1 or the like has such a technical problem that (i) if the sound volume (or sound pressure level) is set large by a user and (ii) if a signal level is large in a band in the vicinity of a low-range limited band (or low frequency band) in a reproduction frequency band which depends on the performances of the speaker, a sound reproduced from the speaker becomes distorted, or an abnormal noise is generated, and these sound and noise are likely unpleasant for the user. In general, this technical problem is caused by a large amount of displacement (amplitude) of a diaphragm in the speaker, in the band in the vicinity of the low-range limited band described above.

In view of the aforementioned problem, it is therefore an object of the present invention to provide an audio reproducing apparatus and method which allow a high-quality sound to be reproduced even if a sound volume from a speaker is set large by a user, and a computer program which makes a computer function as the audio reproducing apparatus.

### Means for Solving the Subject

### (Audio Reproducing Apparatus)

Hereinafter, the audio reproducing apparatus of the present invention will be explained.

The above object of the present invention can be achieved by an audio reproducing apparatus for reproducing an audio signal during signal processing, provided with: a signal level detecting device for detecting a signal level (or signal size) of the audio signal; a sound pressure level adjusting device (or sound volume adjusting device: an operation by a user) for hanging a sound pressure level (or an amplification factor, sound volume, and volume) which indicates an amplification factor of the audio signal; a frequency characteristic correcting device (or equalizer) for correcting at least a frequency characteristic of the audio signal on the basis of a correction amount; and a controlling device for (i) determining the correction amount on the basis of the signal level and the sound pressure level and (ii) sequentially controlling the frequency characteristic correcting device to perform the correction on the basis of the determined correction amount.

According to the audio reproducing apparatus of the present invention, firstly, the signal level (or signal size) of the audio signal is detected by the signal level detecting device. Simultaneously with or in tandem with this, the sound pressure level (or an amplification factor, sound volume, and volume) which indicates the amplification factor of the audio signal is changed by the sound pressure level adjusting device (or sound volume adjusting device) on the basis of, for example, a user's operation.

Then, the correction amount is corrected by the controlling device on the basis of the signal level and the sound pressure level.

Then, under the sequential control of the controlling device, the frequency characteristic of the audio signal is corrected by the frequency characteristic correcting device on the basis of the determined correction amount.

In particular, in the present invention, even if (i) the sound pressure level is set large by a user and (ii) the signal level is large in a band in the vicinity of a low-range limited band in a reproduction frequency band which depends on the performances of a speaker, at least the frequency characteristic of the audio signal is corrected on the basis of (or in conjunction with) the size of the sound pressure level and the size of the signal level. Specifically, the frequency characteristic of the audio signal in the band in the vicinity of the low-range limited band is attenuated or boosted on the basis of the correction amount determined on the basis of the size of the sound pressure level and the size of the signal level.

As a result, it is possible to reduce the occurrence of the distortion of a sound reproduced from the speaker or the generation of an abnormal noise (which is called a failure of the speaker), to thereby reproduce a high-quality sound at large volume.

In one aspect of the audio reproducing apparatus of the present invention, the audio reproducing apparatus is further provided with a speaker for reproducing the audio signal, and the frequency characteristic correcting device (or equalizer) attenuates or boosts the frequency characteristic of the audio signal on the basis of the correction amount, in a low-range limited ban d in a reproduction frequency band of the speaker, in order to correct a particular frequency band included in the frequency characteristic.

According to this aspect, it is possible to reduce the occurrence of the distortion of a sound reproduced from the speaker or the generation of an abnormal noise (which is called a failure of the speaker), in the band in the vicinity of the low-range limited band in the reproduction frequency band which depends on the performances of the speaker.

In another aspect of the audio reproducing apparatus of the present invention, the audio reproducing apparatus is further provided with a speaker for reproducing the audio signal, and the frequency characteristic correcting device (or equalizer) attenuates or boosts the frequency characteristic of the audio signal on the basis of the correction amount, in an antiresonance frequency band of the speaker, in order to correct a particular frequency band included in the frequency characteristic.

According to this aspect, it is possible to further reduce the occurrence of the distortion of a sound reproduced from the speaker or the generation of an abnormal noise (which is called a failure of the speaker), in the antiresonance frequency band of the speaker.

In another aspect of the audio reproducing apparatus of the present invention, the audio reproducing apparatus is further provided with a port type speaker for reproducing the audio signal, and the frequency characteristic correcting device (or equalizer) attenuates or boosts the frequency characteristic of the audio signal on the basis of the correction amount, in a port resonance frequency band of the speaker, in order to correct a particular frequency band included in the frequency characteristic.

According to this aspect, it is possible to further reduce the occurrence of the distortion of a sound reproduced from the speaker or the generation of an abnormal noise (which is called a failure of the speaker), in the port resonance frequency band of the speaker.

In another aspect of the audio reproducing apparatus of the present invention, the audio reproducing apparatus is further provided with a sealing type speaker for reproducing the audio signal, the speaker having a diaphragm, and the frequency characteristic correcting device (or equalizer) attenuates or boosts the frequency characteristic of the audio signal on the basis of the correction amount, in a frequency band in which displacement of the diaphragm is maximal, in order to correct a particular frequency band included in the frequency characteristic.

According to this aspect, it is possible to further reduce the occurrence of the distortion of a sound reproduced from the speaker or the generation of an abnormal noise (which is called a failure of the speaker), in the frequency band in which displacement of the diaphragm provided for the speaker is maximal.

In an aspect associated with the aforementioned controlling device, the controlling device may control the frequency characteristic correcting device to keep attenuating or boosting the frequency characteristic of the audio signal on the basis of the correction amount, in a frequency band which is lower than the particular frequency band.

By virtue of such construction, it is possible to further reduce the occurrence of the distortion of a sound reproduced from the speaker or the generation of an abnormal noise (which is called a failure of the speaker), in the frequency band which is lower than the particular frequency band.

In another aspect of the audio reproducing apparatus of the present invention, the controlling device increases the correction amount in accordance with an extent that at least one of the signal level and the sound pressure level increases.

According to this aspect, it is possible to correct the frequency characteristic on the basis of the correction amount which more accurately and highly accurately corresponds to the size of the signal level and the size of the sound pressure level.

In another aspect of the audio reproducing apparatus of the present invention, the controlling device increases the correction amount if the signal level is greater than a first predetermined value and the sound pressure level is greater than a second predetermined value.

According to this aspect, it is possible to correct the frequency characteristic on the basis of the correction amount which is more accurately and highly accurately based on (i) the comparison of the size of the signal level and the first predetermined value, and (ii) the comparison of the size of the sound pressure level and the second predetermined value.

In another aspect of the audio reproducing apparatus of the present invention, the controlling device increases the correction amount in accordance with a first extent that the signal level increases and a second extent that the sound pressure level increases if the first extent is substantially equal to the second extent.

According to this aspect, it is possible to correct the frequency characteristic on the basis of the correction amount which is more accurately and highly accurately based on (i) the first extent that the signal level increases and (ii) the second extent that the sound pressure level increases and that is substantially equal to the first extent.

In another aspect of the audio reproducing apparatus of the present invention, the controlling device increases the correction amount in accordance with a first extent that the signal level increases and a second extent that the sound pressure level increases if the first extent is not equal to the second extent.

According to this aspect, it is possible to correct the frequency characteristic on the basis of the correction amount which is more accurately and highly accurately based on (i) the first extent that the signal level increases and (ii) the second extent that the sound pressure level increases and that is not equal to the first extent.

In another aspect of the audio reproducing apparatus of the present invention, the controlling device controls the frequency characteristic correcting device not to correct the frequency characteristic (i) if the signal level is smaller than a first predetermined value or (ii) if the sound pressure level is smaller than a second predetermined value.

According to this aspect, the frequency characteristic is not corrected (i) if the signal level is smaller than the first predetermined value or (ii) if the sound pressure level is smaller than the second predetermined value. Therefore, it is possible to correct the frequency characteristic, more efficiently.

In another aspect of the audio reproducing apparatus of the present invention, the controlling device controls the frequency characteristic correcting device (i) to attenuate the frequency characteristic of the audio signal on the basis of the correction amount if at least one of the signal level and the sound pressure level is relatively high, (ii) to boost the frequency characteristic of the audio signal on the basis of the correction amount if the one of the signal level and the sound pressure level is relatively low, and (iii) not to correct the frequency characteristic if the one of the signal level and the sound pressure level is relatively moderate.

According to this aspect, it is possible to correct the frequency characteristic on the basis of the correction amount which more accurately and highly accurately corresponds to the size of the signal level and the size of the sound pressure level so as to attenuate or boost the frequency characteristic.

### (Audio Reproducing Method)

Hereinafter, the audio reproducing method of the present invention will be explained.

The above object of the present invention can be also achieved by an audio reproducing method in an audio reproducing apparatus for reproducing an audio signal during signal processing, the method provided with: a signal level detecting process of detecting a signal level (or signal size) of the audio signal; a sound pressure level adjusting process (or sound volume adjusting device: an operation by a user) of changing a sound pressure level (an amplification factor, sound volume, and volume) which indicates an amplification factor of the audio signal; a frequency characteristic correcting process of correcting at least a frequency characteristic of the audio signal on the basis of a correction amount; and a controlling process (or equalizer) of (i) determining the correction amount on the basis of the signal level and the sound pressure level and (ii) sequentially controlling the frequency characteristic correcting process to perform the correction on the basis of the determined correction amount.

According to the audio reproducing method of the present invention, it is possible to receive the various benefits owned by the aforementioned audio reproducing apparatus of the present invention.

Incidentally, in response to the aforementioned various aspects of the audio reproducing apparatus of the present invention, the audio reproducing method of the present invention can also employ various aspects.

### (Computer Program)

Hereinafter, the computer program of the present invention will be explained.

The above object of the present invention can be also achieved by a computer program for signal processing to control a computer provided in the aforementioned audio reproducing apparatus of the present invention (including its various aspects), the computer program malting the computer function as at least one portion of the signal level detecting device, the sound pressure level adjusting device, the frequency characteristic correcting device, and the controlling device.

According to the computer program of the present invention, the aforementioned audio reproducing apparatus of the present invention can be relatively easily realized as a computer reads and executes the computer program from a program storage device, such as a ROM, a CD-ROM, a DVD-ROM, and a hard disk, or as it executes the computer program after downloading the program through a communication device.

Incidentally, in response to the various aspects of the aforementioned audio reproducing apparatus of the present invention, the computer program of the present invention can also employ various aspects.

The above object of the present invention can be also achieved by a computer program product in a computer-readable medium for tangibly embodying a program of instructions executable by a computer provided in the aforementioned audio reproducing apparatus of the present invention (including its various aspects), the computer program product making the computer function as at least one portion of the signal level detecting device, the sound pressure level adjusting device, the frequency characteristic correcting device, and the controlling device.

According to the computer program product of the present invention, the aforementioned audio reproducing apparatus of the present invention can be embodied relatively readily, by loading the computer program product from a recording medium for storing the computer program product, such as a ROM (Read Only Memory), a CD-ROM (Compact Disc-Read Only Memory), a DVD-ROM (DVD Read Only Memory), a hard disk or the like, into the computer, or by downloading the computer program product, which may be a carrier wave, into the computer via a communication device. More specifically, the computer program product may include computer readable codes to cause the computer (or may comprise computer readable instructions for causing the computer) to function as the aforementioned audio reproducing apparatus of the present invention.

These effects and other advantages of the present invention will become more apparent from the embodiments explained below.

As explained above, according to the audio reproducing apparatus of the present invention, it is provided with the signal level detecting device, the sound pressure level adjusting device, the frequency characteristic correcting device, and the controlling device. According to the information reproducing method of the present invention, it is provided with the signal level detecting process, the sound pressure level adjusting process, the frequency characteristic correcting process, and the controlling process. Therefore, it is possible to reduce the occurrence of the distortion of a sound reproduced from the speaker or the generation of an abnormal noise (which is called a failure of the speaker), to thereby reproduce a high-quality sound at large volume.

Moreover, according to the computer program of the present invention, it makes a computer function as the aforementioned audio reproducing apparatus. This enables the audio reproducing apparatus to reduce the occurrence of the distortion of a sound reproduced from the speaker or the generation of an abnormal noise (which is called a failure of the speaker), to thereby reproduce a high-quality sound at large volume.

### BRIEF DESCRIPTION OF DRAWINGS

FIG. 1 is a block diagram showing the basic structure of an audio reproducing apparatus of the present invention.

FIG. 2 is a flowchart showing the operation principle of the audio reproducing apparatus of the present invention.

FIG. 3 are a graph showing a frequency characteristic based on an attenuation amount which changes depending on the size of a signal level of the present invention (FIG. 3(a)) and a graph showing a frequency characteristic based on an attenuation amount which changes depending on the size of a sound pressure level of the present invention (FIG. 3(b)).

FIG. 4 are a graph two-dimensionally showing an attenuation amount which changes depending on the sizes of both the signal level and the sound pressure level of the present invention (FIG. 4(a)) and a graph three-dimensionally showing the attenuation amount which changes depending on the sizes of both the signal level and the sound pressure level of the present invention (FIG. 4(b)).

FIG. 5 are a graph two-dimensionally showing another attenuation amount which changes depending on the sizes of both the signal level and the sound pressure level of the present invention (FIG. 5(a)) and a graph two-dimensionally showing another attenuation amount which changes depending on the sizes of both the signal level and the sound pressure level of the present invention (FIG. 5(b)).

FIG. 6 are a sound pressure level-frequency characteristic diagram in a bass reflex type speaker (FIG. 6(a)) and a flow rate-frequency characteristic diagram in a port portion (FIG. 6(b)) to determine one specific example of a particular frequency band in the present invention.

FIG. 7 are a sound pressure level frequency characteristic diagram in a sealing type speaker (FIG. 7(a)) and a frequency characteristic diagram of displacement of a diaphragm (FIG. 7(b)) to determine another specific example of the particular frequency band in the present invention.

FIG. 8 is a block diagram showing the basic structure of a second embodiment of the audio reproducing apparatus of the present invention.

FIG. 9 is a flowchart showing the operation principle of the second embodiment of the audio reproducing apparatus of the present invention.

FIG. 10 are a graph showing a frequency characteristic based on a boost amount which changes depending on the size of the signal level of the present invention (FIG. 10(a)) and a graph showing a frequency characteristic based on an attenuation amount which changes depending on the size of the sound pressure level of the present invention (FIG. 10(b)).

FIG. 11 are a graph two-dimensionally showing a boost amount which changes depending on the sizes of both the signal level and the sound pressure level of the present invention (FIG. 11(a)) and a graph three-dimensionally showing a boost amount which changes depending on the sizes of both the signal level and the sound pressure level of the present invention (FIG. 11(b)).

FIG. 12 is a diagram showing gain transition with frequency as a parameter, i.e. a gain-frequency characteristic diagram.

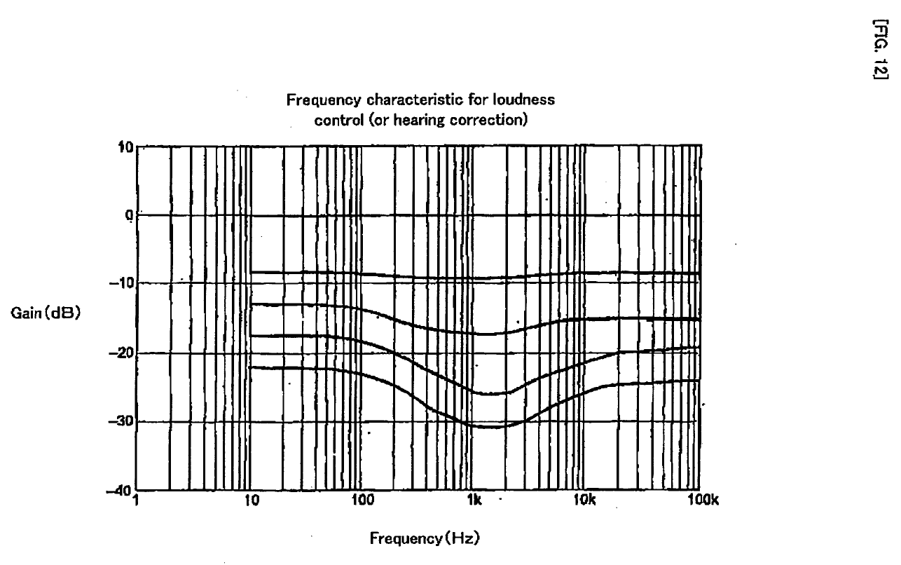

### DESCRIPTION OF REFERENCE CODES

100 audio reproducing apparatus
101 input terminal
102 signal level detecting device
103 attenuation amount controlling device
104 volume adjusting device
105 electronic volume integrated circuit
106 frequency characteristic correcting device
107 amplifier
108 speaker
200 second frequency characteristic correcting device

### BEST MODE FOR CARRYING OUT THE INVENTION

Hereinafter, the best mode for carrying out the present invention will be explained in each embodiment in order with reference to the drawings.

### (1) First Embodiment of Audio Reproducing Apparatus

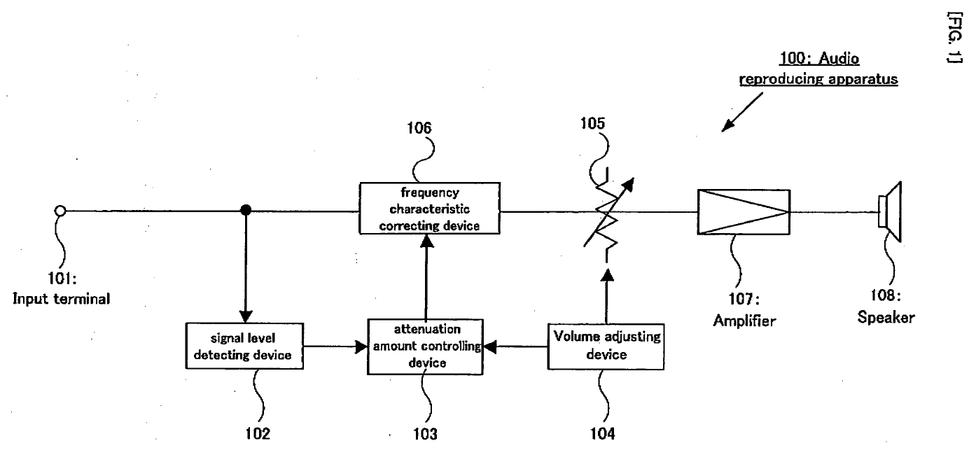

Firstly, with reference to FIG. 1 to FIG. 7, the audio reproducing apparatus of the present invention will be explained.

### (1-1) Basic Structure

Firstly, with reference to FIG. 1, the basic structure of the audio reproducing apparatus of the present invention will be explained. FIG. 1 is a block diagram showing the basic structure of the audio reproducing apparatus of the present invention.

As shown in FIG. 1, an audio reproducing apparatus 100 of the present invention, such as an AV receiver, is provided with: (i) an input terminal 101 to which an audio signal is inputted; (ii) a signal level detecting device 102 for detecting a signal level of the audio signal; (iii) an attenuation amount controlling device 103, which is one specific example of the “controlling device” of the present invention; (iv) a volume adjusting device 104, which is one specific example of the “sound pressure level adjusting device” of the present invention; (v) an electronic volume integrated circuit 105; (vi) a frequency characteristic correcting device 106, such as an equalizer, which can attenuate a signal level in a particular frequency band (in other words, a frequency characteristic of the audio signal) on the basis of a determined attenuation amount (or correction amount); (vii) an amplifier 107; and (viii) a speaker 108. Incidentally, on the frequency characteristic correcting device 106, the particular frequency band is set to 56 (Hz), the maximum attenuation amount is set to 6 (dB), and a quality factor or resonance sharpness (Q) is set to 4. Moreover, the frequency characteristic correcting device 106 may be able to continuously change the particular frequency band.

### (1-2) Operation Principle

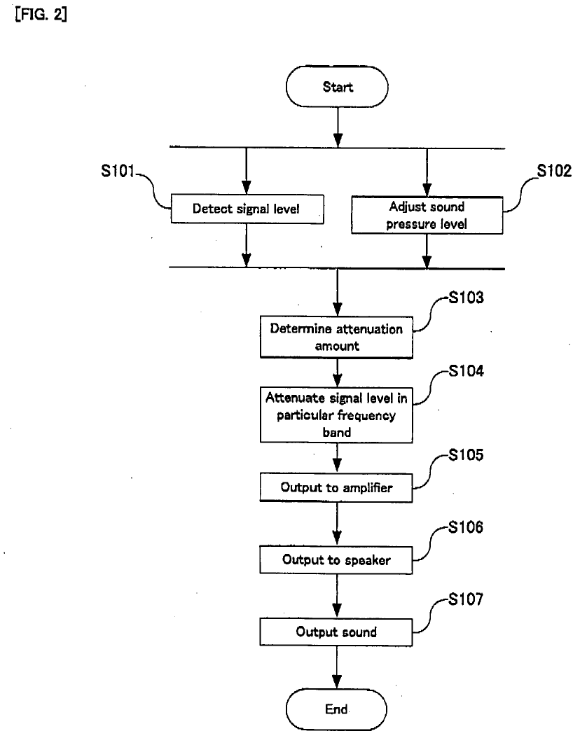

Next, with reference to the aforementioned FIG. 1, if necessary, in addition to FIG. 2, an explanation will be given on the operation principle of the audio reproducing apparatus of the present invention. FIG. 2 is a flowchart showing the operation principle of the audio reproducing apparatus of the present invention.

As shown in FIG. 2, firstly, a signal level of an audio signal inputted from the input terminal 101 is detected by the signal level detecting device 102 on the audio reproducing apparatus 100 of the present invention (step S101).

Simultaneously with or in tandem with the step S101, a sound pressure level is adjusted by the volume adjusting device 104, for example, under a knob operation by a user (step S102).

Then, a certain attenuation amount, which is one specific example of the “correction amount” of the present invention, is determined by the attenuation amount controlling device 103 on the basis of (i) the detected signal level and (ii) the adjusted sound pressure level (step S103). Incidentally, the method of determining the attenuation amount will be explained in Correction Principle of Frequency Characteristic described later.

Then, the level of a particular frequency band of the audio signal is attenuated by the frequency characteristic correcting device 106 by the determined attenuation amount (or correction amount) (step S104). Incidentally, the method of determining the particular frequency band will be explained in Correction Principle of Frequency Characteristic described later.

Then, the audio signal in which the level of the particular frequency band of the audio signal is attenuated is outputted by the electronic volume integrated circuit 105 to the amplifier 107, on the basis of the sound pressure level which is adjusted by the volume adjusting device 104 (step S105).

Then, the audio signal amplified by the amplifier 107 is outputted to the speaker (step S106).

Lastly, a sound including the audio signal in which the level of the particular frequency band of the audio signal is attenuated is outputted by the speaker 108 (step S107).

### (1-3) Correction Principle of Frequency Characteristics

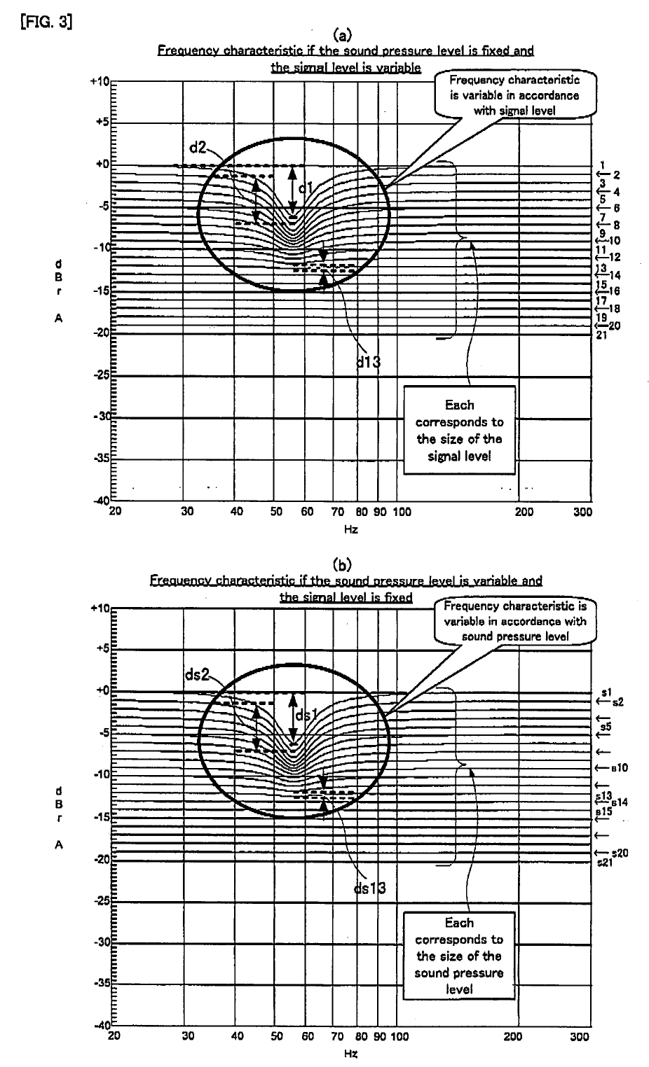

Next, with reference to FIG. 3 to FIG. 7, an explanation will be given on one and another specific examples of the correction principle of the frequency characteristic of the present invention.

### (1-3-1) Attenuation Amount Which Changes Depending on the Size of the Signal Level

Firstly, with reference to FIG. 3(a), an explanation will be given on one specific example of the correction principle of the frequency characteristic based on the attenuation amount which changes depending on the size of the signal level. FIG. 3(a) is a graph showing the frequency characteristic based on the attenuation amount which changes depending on the size of the signal level of the present invention. Incidentally, the horizontal axis in FIG. 3(a) indicates frequency (Hz: Hertz), and the vertical axis indicates the level (dB: decibel) of the audio signal which is outputted from the audio reproducing apparatus 100.

As shown in FIG. 3(a), the audio signal is attenuated by the frequency characteristic correcting device 106 of the present invention in the particular frequency band by the attenuation amount which changes depending on the size of the signal level. This attenuation amount is sequentially determined by the attenuation amount controlling device 103. In particular, the size of the sound pressure level is fixed in FIG. 3(a).

Specifically, as shown in a curve “1” which is located on the top in FIG. 3(a), which has the highest signal level, and which corresponds to the frequency characteristic of the audio signal outputted from the audio reproducing apparatus 100, the audio signal is attenuated by the maximum attenuation amount “d1” (incidentally, d1=6 (dB), and quality factor (Q)=4) in the particular frequency band (e.g. 56 (Hz)). In the same manner, as shown in a curve “2” which is located on the second top in FIG. 3(a), which has the second highest signal level, and which corresponds to the frequency characteristic of the audio signal outputted from the audio reproducing apparatus 100, the audio signal is attenuated by the second largest attenuation amount “d2” in the particular frequency band (e.g. 56 (Hz)). In the same manner, as shown in a curve “13” which is located on the 13th top in FIG. 3(a), which has the 13th highest signal level, and which corresponds to the frequency characteristic of the audio signal outputted from the audio reproducing apparatus 100, the audio signal is attenuated by the 13th largest (i.e. the smallest) attenuation amount “d13” in the particular frequency band (e.g. 56 (Hz)).

On the other hand, as shown in a curve “14” which is located on the 14th top in FIG. 3(a), which has the 14th highest signal level, and which corresponds to the frequency characteristic of the audio signal outputted from the audio reproducing apparatus 100, the audio signal is not attenuated in the particular frequency band (e.g. 56 (Hz)). In the same manner, as shown in a curve “15” which is located on the 15th top in FIG. 3(a), which has the 15th highest signal level, and which corresponds to the frequency characteristic of the audio signal outputted from the audio reproducing apparatus 100, the audio signal is also not attenuated in the particular frequency band (e.g. 56 (Hz)). In the same manner, as shown in a curve “21” which is located on the 21st top (i.e. on the bottom) in FIG. 3(a), which has the 21st highest (.e. lowest) signal level, and which corresponds to the frequency characteristic of the audio signal outputted from the audio reproducing apparatus 100, the audio signal is also not attenuated in the particular frequency band (e.g. 56 (Hz)).

As described above, in one specific example of the correction principle of the frequency characteristic of the present invention, (i) the particular frequency band of the audio signal, which is inputted to the audio reproducing apparatus 100, is attenuated by the attenuation amount (i.e. the attenuation amount of a size which is proportional to the size of the signal level) if the signal level is relatively high, and (ii) the frequency characteristic is not corrected, i.e., it is set to have flat property if the signal level is relatively low.

### (1-3-2) Attenuation Amount Which Changes Depending on the Size of the Sound Pressure Level

Next, with reference to FIG. 3(b), an explanation will be given on one specific example of the correction principle of the frequency characteristic based on the attenuation amount which changes depending on the size of the sound pressure level. FIG. 3(b) is a graph showing the frequency characteristic based on the attenuation amount which changes depending on the size of the sound pressure level of the present invention. Incidentally, the horizontal axis in FIG. 3(b) indicates frequency (Hz: hertz), and the vertical axis indicates the level (dB: decibel) of the audio signal which is outputted from the audio reproducing apparatus 100.

As shown in FIG. 3(b), the audio signal is attenuated by the frequency characteristic correcting device 106 of the present invention in the particular frequency band by the attenuation amount which changes depending on the size of the sound pressure level. This attenuation amount is sequentially determined by the attenuation amount controlling device 103. In particular, the size of the signal level is fixed in FIG. 3(b).

Specifically, as shown in a curve “s1” which is located on the top in FIG. 3(b), which has the highest sound pressure level, and which corresponds to the frequency characteristic of the audio signal outputted from the audio reproducing apparatus 100, the audio signal is attenuated by the maximum attenuation amount “ds1” in the particular frequency band (e.g. 56 (Hz)). In the same manner, as shown in a curve “s2” which is located on the second top in FIG. 3(b), which has the second highest sound pressure level, and which corresponds to the frequency characteristic of the audio signal outputted from the audio reproducing apparatus 100, the audio signal is attenuated by the second largest attenuation amount “ds2” in the particular frequency band (e.g. 56 (Hz)). In the same manner, as shown in a curve “s13” which is located on the 13th top in FIG. 3(b), which has the 13th highest sound pressure level and which corresponds to the frequency characteristic of the audio signal outputted from the audio reproducing apparatus 100, the audio signal is attenuated by the 13th largest (i.e. the smallest) attenuation amount “ds13” in the particular frequency band (e.g. 56 (Hz)).

On the other hand, as shown in a curve “s14” which is located on the 14th top in FIG. 3(b), which has the 14th highest sound pressure level, and which corresponds to the frequency characteristic of the audio signal outputted from the audio reproducing apparatus 100, the audio signal is not attenuated in the particular frequency band (e.g. 56 (Hz)). In the same manner, as shown in a curve “s15” which is located on the 15th top in FIG. 3(b), which has the 15th highest sound pressure level, and which corresponds to the frequency characteristic of the audio signal outputted from the audio reproducing apparatus 100, the audio signal is also not attenuated in the particular frequency band (e.g. 56 (Hz)). In the same manner, as shown in a curve “s21” which is located on the 21st top (i.e. on the bottom) in FIG. 3(b), which has the 21st highest (i.e. lowest) sound pressure level, and which corresponds to the frequency characteristic of the audio signal outputted from the audio reproducing apparatus 100, the audio signal is also not attenuated in the particular frequency band (e.g. 56 (Hz).

As described above, in another specific example of the correction principle of the frequency characteristic of the present invention, (i) the particular frequency band of the audio signal, which is inputted to the audio reproducing apparatus 100, is attenuated by the attenuation amount (i.e. the attenuation amount of a size which is proportional to the size of the sound pressure level) if the sound pressure level is relatively high, and (ii) the frequency characteristic is not corrected, i.e., it is set to have flat property if the sound pressure level is relatively low.

### (1-3-3) Attenuation Amount Which Changes Depending on the Sizes of Both the Signal Level and the Sound Pressure Level

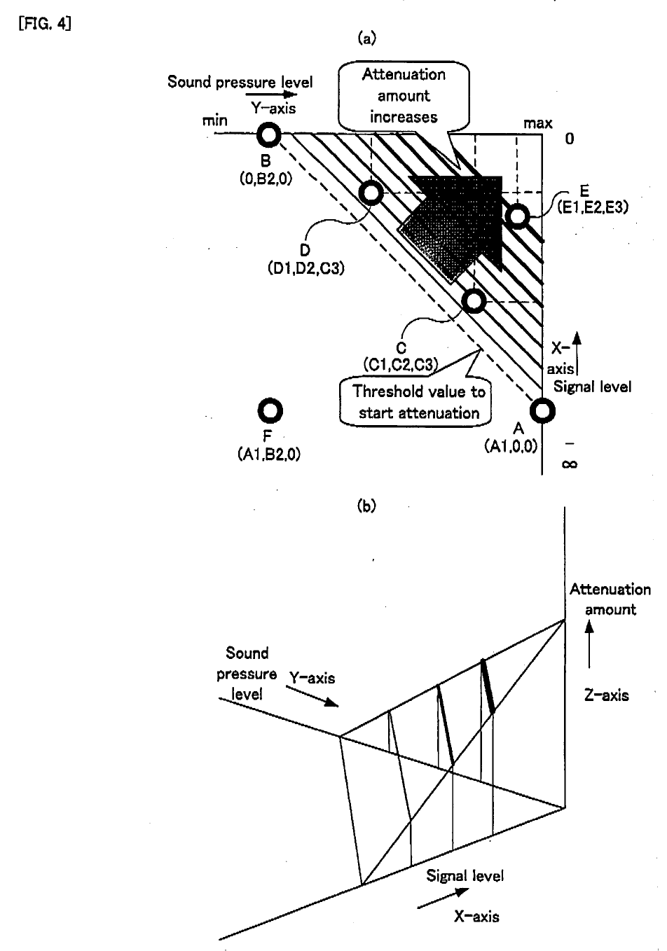

Next, with reference to FIG. 4, an explanation will be given on another specific example of the correction principle of the frequency characteristic based on the attenuation amount which changes depending on the sizes of both the signal level and the sound pressure level. FIG. 4 are a graph two-dimensionally showing the attenuation amount which changes depending on the sizes of both the signal level and the sound pressure level of the present invention (FIG. 4(a)) and a graph three-dimensionally showing the attenuation amount which changes depending on the sizes of both the signal level and the sound pressure level of the present invention (FIG. 4(b)). Incidentally, an X axis in FIG. 4(a) and FIG. 4(b) indicates the level (dB: decibel) of the signal level, an Y axis indicates the size (dB: decibel) of the sound pressure level, and a Z axis indicates the size of the attenuation amount. Moreover, the thickness of lines in FIG. 4(a) relatively indicates the size of the attenuation amount.

As shown in FIG. 4(a) and FIG. 4(b), in another specific example of the correction principle of the frequency characteristic of the present invention, the attenuation amount may change depending on the sizes of both the signal level and the sound pressure level. Specifically, the attenuation amount may change depending on the sizes of both the signal level and the sound pressure level which are shown by points that exist in an upper right area of a line which connects a point “A”, ((x-axis coordinate, Y-axis coordinate, Z-axis coordinate)=(A1, 0, 0)) and a point “B” ((x-axis coordinate, Y-axis coordinate, Z-axis coordinate)=(0, B2, 0)) in FIG. 4(a). Incidentally, “A1” shows one example of the “first predetermined value” of the present invention, and “B2” shows one example of the “second predetermined value” of the present invention.

Specifically, as shown in a point “C” ((X-axis coordinate, Y-axis coordinate, Z-axis coordinate)=(C1, C2, C3)), if the signal level is “C1” and the sound pressure level is “C2”, the attenuation amount may be set “C3”. In the same manner, as shown in a point “D” ((X-axis coordinate, Y-axis coordinate, Z-axis coordinate)=(D1, D2, C3)), even if the signal level is “D1” and the sound pressure level is “D2”, the attenuation amount may be set “C3”. Moreover, as shown in a point “E” ((X-axis coordinate, Y-axis coordinate, Z-axis coordinate)=(E1, E2, E3)), if the signal level is “E1” and the sound pressure level is “E2”, the attenuation amount may be set “E3”, wherein “E3” is greater than “C3”.

On the other hand, as shown in a point “F” ((X-axis coordinate, Y-axis coordinate, Z-axis coordinate)=(A1, B2, 0)), if the signal level is “A1” and the sound pressure level is “B2”, the attenuation amount may be set “0”; namely, it may be set not to be attenuated.

### (1-3-4) Another Attenuation Amount Which Changes Depending on the Sizes of Both the Signal Level and the Sound Pressure Level

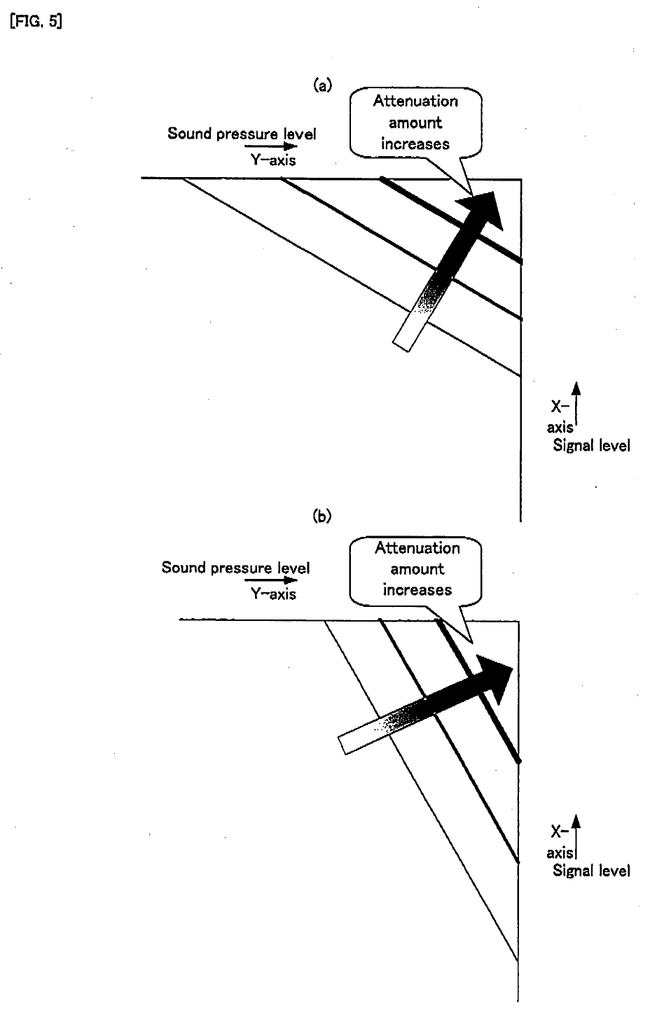

Next, with reference to FIG. 5, an explanation will be given on another attenuation amount which changes depending on the sizes of both the signal level and the sound pressure level. FIG. 5 are a graph two-dimensionally showing another attenuation amount which changes depending on the sizes of both the signal level and the sound pressure level of the present invention (FIG. 5(a)) and a graph two-dimensionally showing another attenuation amount which changes depending on the sizes of both the signal level and the sound pressure level of the present invention (FIG. 5(b)).

As shown in FIG. 5(a), the extent of an increase in the attenuation amount which changes depending on the size of the signal level may be greater than the extent of an increase in the attenuation amount which changes depending on the size of the sound pressure level.

Alternatively, as shown in FIG. 5(b), the extent of an increase in the attenuation amount which changes depending on the size of the signal level may be less than the extent of an increase in the attenuation amount which changes depending on the size of the sound pressure level.

### (1-3-5) One Specific Example of Particular Frequency Band

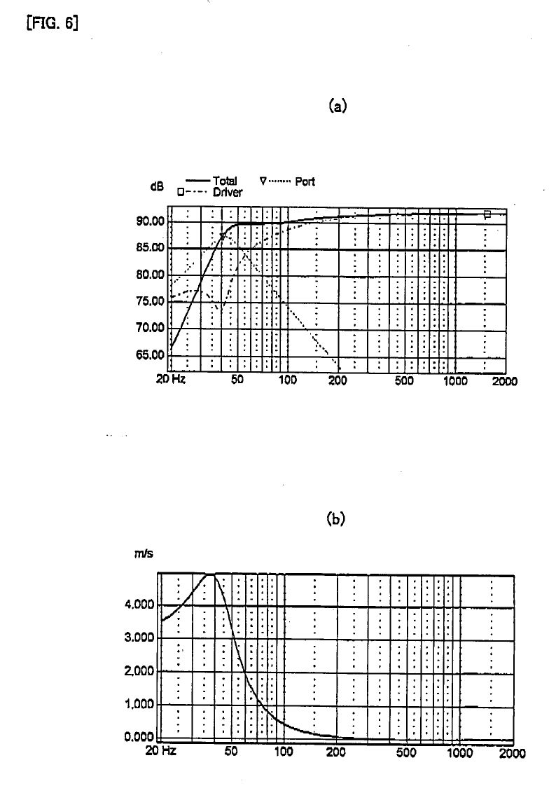

Next, with reference to FIG. 6, an explanation will be given on one specific example of the particular frequency band in the present invention. FIG. 6 are a sound pressure level-frequency characteristic diagram in a bass reflex type speaker (FIG. 6(a)) and a flow rate-frequency characteristic diagram in a port portion (FIG. 6(b)) to determine one specific example of a particular frequency band in the present invention. Incidentally, these frequency characteristic diagrams are obtained by various measurements under the following three conditions: (i) the volume of the speaker is 25 (Liter), (ii) the diameter in the port is 5 (cm), and (iii) a resonance frequency in the port is 40 (Hz) when the sound pressure level corresponding to an electric power of 1 (W) is outputted.

As shown in FIG. 6(a) and FIG. 6(b), the “particular frequency band” of the present invention may be a frequency band centered on a frequency of about 40 (Hz) in the bass reflex type speaker. More specifically, the frequency band centered on approximately 40 (Hz) may be in a range to hold an error of about 20 percentages. Specifically, the frequency band centered on approximately 40 (Hz) may be a band in a range of about 32 (Hz) to about 48 (Hz). Moreover, alternatively, it may be a band which satisfies the condition that the quality factor (or resonance sharpness) is between 2 and 6.

Specifically, in the bass reflex type speaker in the embodiment, as shown in a solid-line curve in FIG. 6(a), it is clear that sound pressure level, which is outputted from the speaker, (i) has an amplification factor which starts to be significantly reduced in the vicinity of about 40 (Hz), and (ii) becomes generally constant (or flat) at the frequency that is greater than about 50 (Hz). In particular, the frequency characteristic of the sound pressure level on hearing of a human being can be obtained by the sum of (i) the frequency characteristic of the sound pressure level from the port shown in a dotted line (which has inverted triangle marks) in FIG. 6(a) and (ii) the frequency characteristic of the sound pressure level from the speaker shown in an alternate long and short line (which has square marks) in FIG. 6(a). In addition, as shown in a solid-line curve in FIG. 6(b), in the bass reflex type speaker in the embodiment, it is clear that the flow rate of an air which moves in the port has the maximum value in the frequency band centered on about 40 (Hz) (which is called the resonance frequency in the port).

### (1-3-6) Another Specific Example of Particular Frequency Band

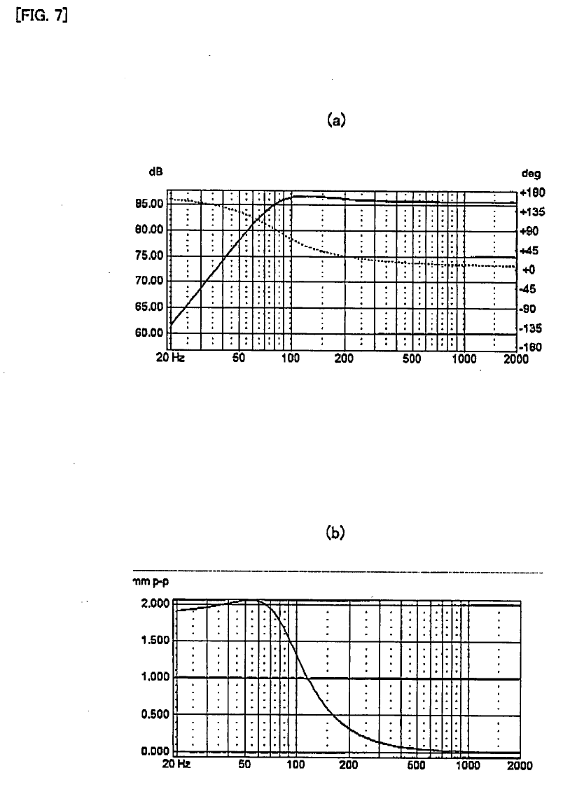

Next, with reference to FIG. 7, an explanation will be given on another specific example of the particular frequency band in the present invention. FIG. 7 are a sound pressure level-frequency characteristic diagram in a sealing type speaker (FIG. 7(a)) and a frequency characteristic diagram of displacement of a diaphragm (FIG. 7(b)) to determine another specific example of a particular frequency band in the present invention.

As shown in FIG. 7(a) and FIG. 7(b), the “particular frequency band” of the present invention may be a frequency band centered on a frequency of about 60 (Hz) in the sealing type speaker.

Specifically, in the sealing type speaker in the embodiment, as shown in a solid-line curve in FIG. 7(a), it is clear that the sound pressure level on hearing of a human being has an amplification factor which starts to be significantly attenuated in a band of about 60 to 80 (Hz) and that it becomes generally constant (or flat) at the frequency that is greater than about 90 (Hz). In addition, as shown in a solid-line curve in FIG. 7(b), in the sealing type speaker in the embodiment, it is clear that the diaphragm provided for the speaker has the maximum value in the frequency band centered on about 60 (Hz).

As explained in the aforementioned one and another specific examples of the particular frequency band, the particular frequency band is determined in view of the frequency characteristics of various parameters as described above, in the bass reflex type speaker and the sealing type speaker.

In particular, in the embodiment, the speaker may be of another type, such as a passive radiator type speaker. In this case, the particular frequency band may be determined from a resonance frequency based on acoustic properties and mechanical properties in a cabinet of the speaker.

Specifically, out of the resonance frequency in the port, the resonance frequency of the passive radiator type speaker, and the resonance frequency based on acoustic properties and mechanical properties, for example, a frequency band which is lower than 100 (Hz) may be set as the particular frequency band.

Moreover, in particular, a prefixed value may be set for the particular frequency band of the present invention, depending on the performances or the like of the speaker which is provided for the audio reproducing apparatus, in the manufacture thereof or the like.

Alternatively, the particular frequency band may be able to be automatically set by the audio reproducing apparatus in a method of measurement with a microphone or the like, depending on the performances or the like of the speaker which is purchased independently and separately. Moreover, alternatively, the particular frequency band may be able to be automatically set by the audio reproducing apparatus from among a plurality of values. Furthermore, alternatively, the particular frequency band may be able to be manually set by a user from among a plurality of values.

### (1-3-7) Effect of First Embodiment

As described above, in the first embodiment, even if (i) the sound pressure level is set large by a user and (ii) the signal level is large in the band in the vicinity of the low-range limited band in the reproduction frequency band which depends on the performances of the speaker, at least the frequency characteristic of the audio signal is corrected on the basis of (or in conjunction with) the size of the sound pressure level and the size of the signal level. Specifically, the frequency characteristic of the audio signal in the band in the vicinity of the low-range limited band is attenuated or boosted on the basis of the correction amount determined by the size of the sound pressure level and the size of the signal level.

As a result, it is possible to reduce the occurrence of the distortion of a sound reproduced from the speaker or the generation of an abnormal noise (which is called a failure of the speaker), to thereby reproduce a high-quality sound at large volume.

### (2) Second Embodiment of Audio Reproducing Apparatus

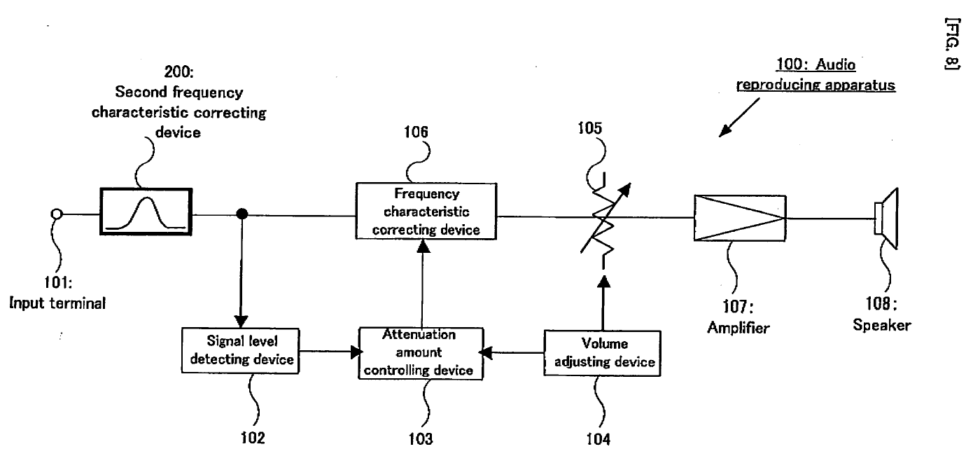

Firstly, with reference to FIG. 8 to FIG. 10, a second embodiment of the audio reproducing apparatus of the present invention will be explained.

### (1-1) Basic Structure and Operation Principle

Firstly, with reference to FIG. 8, the basic structure of the second embodiment of the audio reproducing apparatus of the present invention will be explained. FIG. 8 is a block diagram showing the basic structure of the second embodiment of the audio reproducing apparatus of the present invention. Incidentally, in FIG. 8, the same constituent elements as those in the aforementioned first embodiment carry the same numerical references, and the explanation thereof will be omitted, as occasion demands.

As shown in FIG. 8, the second embodiment of the audio reproducing apparatus of the present invention is further provided with a second frequency characteristic correcting device 200 for boosting the signal level in the particular frequency band (in other words, the frequency characteristic of the audio signal), in addition to the constituent elements in the aforementioned first embodiment. Incidentally, in the second frequency characteristic correcting device 200, the particular frequency band is set to 56 (Hz), the maximum boost amount is set to 10 (dB), and the quality factor or resonance sharpness (Q) is set to 4.5. Moreover, the second frequency characteristic correcting device 200 may be able to fix the particular frequency band.

### (2-2) Operation Principle

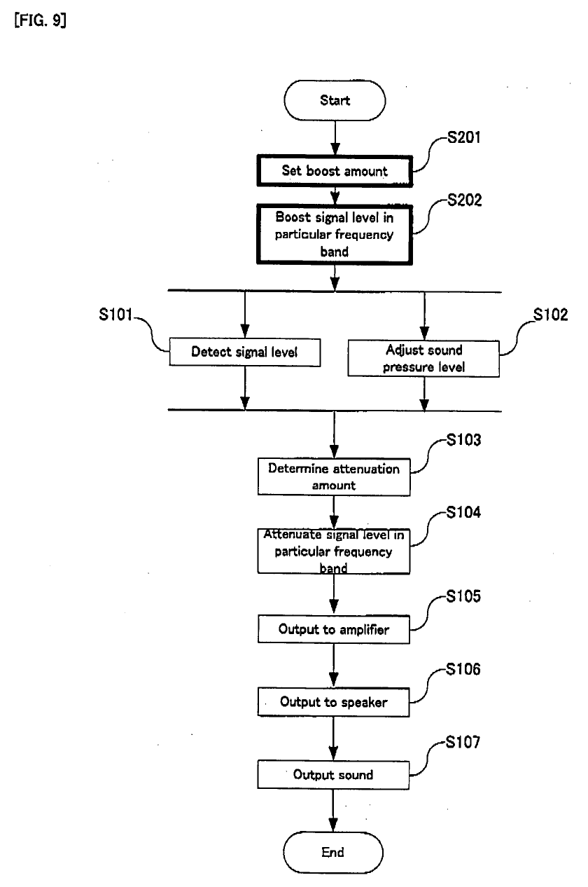

Next, with reference to the aforementioned FIG. 8, if necessary, in addition to FIG. 9, an explanation will be given on the operation principle of the second embodiment of the audio reproducing apparatus of the present invention. FIG. 9 is a flowchart showing the operation principle of the second embodiment of the audio reproducing apparatus of the present invention. Incidentally, in FIG. 9, the same processes as those in the aforementioned first embodiment carry the same step numbers, and the explanation thereof will be omitted, as occasion demands.

Firstly, a boost amount, which is another specific example of the correction amount of the present invention, is set by the second frequency characteristic correcting device 200 on the basis of (i) the detected signal level and (ii) the adjusted sound pressure level (step S201). Incidentally, the method of determining the boost amount will be explained in Correction Principle of Frequency Characteristic described later.

Then, the level of the particular frequency band of the audio signal is boosted by the second frequency characteristic correcting device 106 by the determined boost amount (or correction amount) (step S202).

### (2-3) Correction Principle of Frequency Characteristics

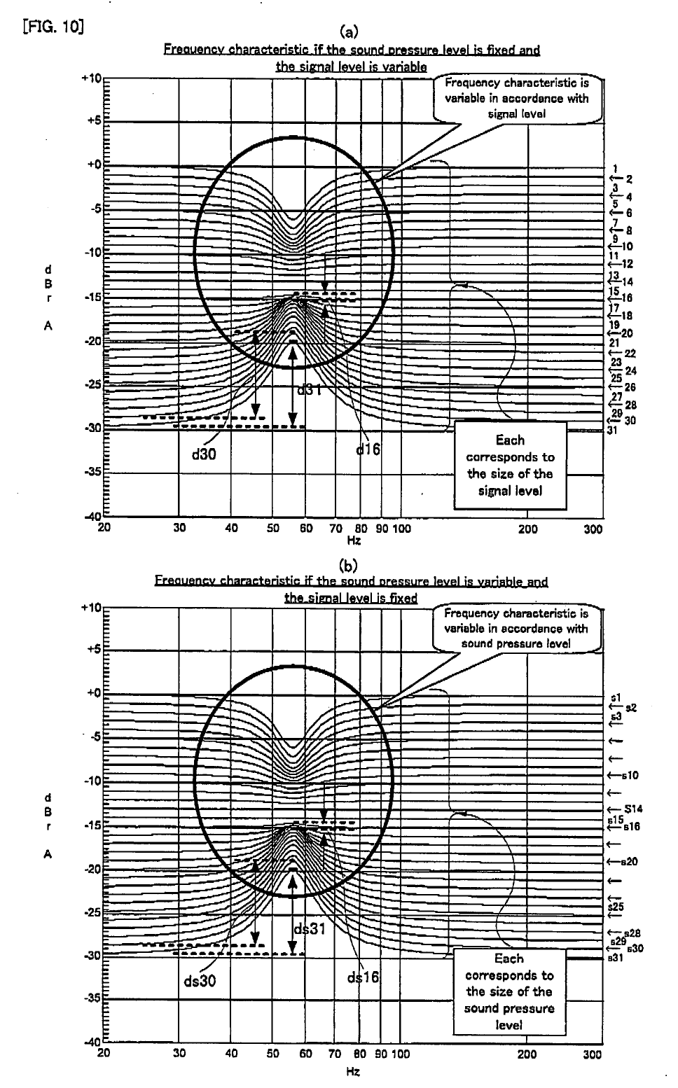

Next, with reference to FIG. 10, an explanation will be given on one and another specific examples of the correction principle of the frequency characteristic of the present invention. In particular, in the second embodiment, the correction of the frequency characteristic by the frequency characteristic correcting device 106 is combined with the correction of the frequency characteristic by the second frequency characteristic correcting device 200.

### (2-3-1) Boost Amount Which Changes Depending on the Size of the Signal Level

Firstly, with reference to FIG. 10(a), an explanation will be given on one specific example of the correction principle of the frequency characteristic based on the boost amount which changes depending on the size of the signal level. FIG. 10(a) is a graph showing the frequency characteristic based on the boost amount which changes depending on the size of the signal level of the present invention. Incidentally, the horizontal axis in FIG. 10(a) indicates frequency (Hz: Hertz), and the vertical axis indicates the level (dB: decibel) of the audio signal which is outputted from the audio reproducing apparatus 100.

As shown in FIG. 10(a), the audio signal is boosted by the second frequency characteristic correcting device 200 in the particular frequency band by the boost amount which changes depending on the size of the signal level. This boost amount may be sequentially determined by the second frequency characteristic correcting device 200. In particular, the size of the sound pressure level is fixed in FIG. 10(a).

Specifically, as shown in a curve “31” which is located on the bottom in FIG. 10(a), which has the lowest signal level, and which corresponds to the frequency characteristic of the audio signal outputted from the audio reproducing apparatus 100, the audio signal is boosted by the maximum boost amount “d31” (incidentally, d31=10 (dB), and quality factor (Q)=4.5) in the particular frequency band (e.g. 56 (Hz)). In the same manner, as shown in a curve “30” which is located on the second bottom in FIG. 10(a), which has the second lowest signal level, and which corresponds to the frequency characteristic of the audio signal outputted from the audio reproducing apparatus 100, the audio signal is boosted by the second largest attenuation amount “d30” in the particular frequency band (e.g. 56 (Hz)). In the same manner, as shown in a curve “16” which is located on the 16th top in FIG. 10(a), which has the 16th highest signal level, and which corresponds to the frequency characteristic of the audio signal outputted from the audio reproducing apparatus 100, the audio signal is boosted by the 16th largest (i.e. the smallest) boost amount “d16” in the particular frequency band (e.g. 56 (Hz)).

On the other hand, as shown in a curve “15” which is located on the 15th top in FIG. 10(a), which has the 15th highest signal level, and which corresponds to the frequency characteristic of the audio signal outputted from the audio reproducing apparatus 100, the audio signal is not boosted in the particular frequency band (e.g. 56 (Hz)).

Incidentally, with regard to curves “1” to “14” which are located on the top to 14th top in FIG. 10(a), which have the maximum signal level to 14th highest signal level, and which correspond to the frequency characteristic of the audio signal outputted from the audio reproducing apparatus 100, an explanation will be omitted because it is substantially the same as that in the aforementioned “(1-3-1) Attenuation amount which changes depending on the size of the signal level”.

As described above, in another specific example of the correction principle of the frequency characteristic of the present invention, (i) the particular frequency band of the audio signal, which is inputted to the audio reproducing apparatus 100, is attenuated by the attenuation amount (i.e. the attenuation amount of a size which is proportional to the size of the signal level) if the signal level is relatively high, (ii) the particular frequency band of the audio signal, which is inputted to the audio reproducing apparatus 100, is boosted by the boost amount (i.e. the boost amount of a size which is inversely proportional to the size of the signal level) if the signal level is relatively low, and (iii) the frequency characteristic is not corrected, i.e. it is set to have flat property, if the signal level is relatively moderate.

### (2-3-2) Boost Amount Which Changes Depending on the Size of the Sound Pressure Level

Next, with reference to FIG. 10(b), an explanation will be given on another specific example of the correction principle of the frequency characteristic based on the boost amount which changes depending on the size of the sound pressure level. FIG. 10(b) is a graph showing the frequency characteristic based on the boost amount which changes depending on the size of the sound pressure level of the present invention. Incidentally, the horizontal axis in FIG. 10(b) indicates frequency (Hz: hertz), and the vertical axis indicates the level (dB: decibel) of the audio signal which is outputted from the audio reproducing apparatus 100.

As shown in FIG. 10(b), the audio signal is boosted by the second frequency characteristic correcting device 200 in the particular frequency band by the boost amount which changes depending on the size of the sound pressure level. This boost amount may be sequentially determined by the second frequency characteristic correcting device 200. In particular, the size of the signal level is fixed in FIG. 10(b).

Specifically, as shown in a curve “s31” which is located on the bottom in FIG. 10(b), which has the lowest sound pressure level and which corresponds to the frequency characteristic of the audio signal outputted from the audio reproducing apparatus 100, the audio signal is boosted by the maximum boost amount “ds31” in the particular frequency band (e.g. 56 (Hz)). In the same manner, as shown in a curve “s30” which is located on the second bottom in FIG. 10(b), which has the second lowest sound pressure level, and which corresponds to the frequency characteristic of the audio signal outputted from the audio reproducing apparatus 100, the audio signal is boosted by the second largest boost amount “ds30” in the particular frequency band (e.g. 56 (Hz)). In the same manner, as shown in a curve “s16” which is located on the 16th top in FIG. 3(b), which has the 16th highest sound pressure level, and which corresponds to the frequency characteristic of the audio signal outputted from the audio reproducing apparatus 100, the audio signal is boosted by the 16th largest (i.e. the smallest) boost amount “ds16” in the particular frequency band (e.g. 56 (Hz)).

On the other hand, as shown in a curve “s15” which is located on the 15th top in FIG. 10(b), which has the 15th highest sound pressure level, and which corresponds to the frequency characteristic of the audio sign outputted from the audio reproducing apparatus 100, the audio signal is not boosted in the particular frequency band (e.g. 56 (Hz)).

Incidentally, with regard to curves “s1” to “s14” which are located on the top to 14th top in FIG. 10(b), which have the maximum signal level to 14th highest signal level, and which correspond to the frequency characteristic of the audio signal outputted from the audio reproducing apparatus 100, an explanation will be omitted because it is substantially the same as that in the aforementioned “(1-3-2) Attenuation amount which changes depending on the size of the sound pressure lever”.

As described above, in another specific example of the correction principle of the frequency characteristic of the present invention, (i) the particular frequency band of the audio signal, which is inputted to the audio reproducing apparatus 100, is attenuated by the attenuation amount (i.e. the attenuation amount of a size which is proportional to the size of the sound pressure level) if the sound pressure level is relatively high, (ii) the particular frequency band of the audio signal, which is inputted to the audio reproducing apparatus 100, is boosted by the boost amount (i.e. the attenuation amount of a size which is inversely proportional to the size of the sound pressure level) if the sound pressure level is relatively low, and (ii) the frequency characteristic is not corrected, i.e. it is set to have flat property, if the sound pressure level is relatively moderate.

### (2-3-3) Boost Amount Which Changes Depending on the Sizes of Both the Signal Level and the Sound Pressure Level

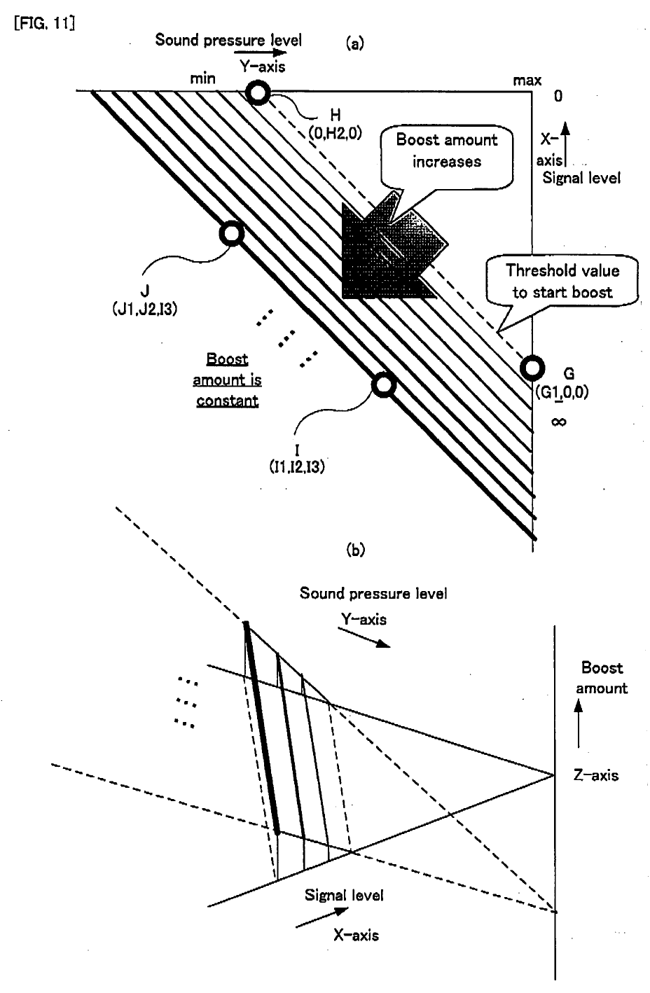

Next, with reference to FIG. 11, an explanation will be given on another specific example of the correction principle of the frequency characteristic based on the attenuation amount which changes depending on the sizes of both the signal level and the sound pressure level. FIG. 11 are a graph two-dimensionally showing the boost amount which changes depending on the sizes of both the signal level and the sound pressure level of the present invention (FIG. 11(a)) and a graph three-dimensionally showing the boost amount which changes depending on the sizes of both the signal level and the sound pressure level of the present invention (FIG. 11(b)). Incidentally, an X axis in FIG. 11(a) and FIG. 11(b) indicates the level (dB: decibel) of the signal level, an Y axis indicates the size (dB: decibel) of the sound pressure level, and a Z axis indicates the size of the boost amount. Moreover, the thickness of lines in FIG. 11(a) relatively indicates the size of the boost amount.

As shown in FIG. 11(a) and FIG. 11(b), in another specific example of the correction principle of the frequency characteristic of the present invention, the boost amount may change depending on the sizes of both the signal level and the sound pressure level. Specifically, the boost amount may change depending on the sizes of both the signal level and the sound pressure level which are shown by points that exist in a lower left area of a line which connects a point “G”, ((X-axis coordinate, Y-axis coordinate, Z-axis coordinate)=(G1, 0, 0)) and a point “H” ((X-axis coordinate, Y-axis coordinate, Z-axis coordinate)=(0, H2, 0)) in FIG. 11(a). Incidentally, “G1” shows another example of the “first predetermined value” of the present invention, and “H2” shows another example of the “second predetermined value” of the present invention.

Specifically, as shown in a point “I” ((X-axis coordinate, Y-axis coordinate, Z-axis coordinate)=(I1, I2, I3)), if the signal level is “I1” and the sound pressure level is “I2”, the boost amount may be set “I3”. In the same manner, as shown in a point “J” ((X-axis coordinate, Y-axis coordinate, Z-axis coordinate)=(J1, J2, I3)), even if the signal level is “J1” and the sound pressure level is “J2”, the boost amount may be set “I3”. In particular, the boost amount may be increased as the signal level or the sound pressure level gets smaller, and the boost amount may be set constant when the boost amount reaches a predetermined boost amount (or the maximum boost amount), as shown in FIG. 11(a).

### (2-3-4) Effect of Second Embodiment

As described above, in the second embodiment, the correction of the frequency characteristic by the frequency characteristic correcting device 106 is combined with the correction of the frequency characteristic by the second frequency characteristic correcting device 200. Therefore, it is possible to correct the frequency characteristic on the basis of the correction amount which more accurately and highly accurately corresponds to the size of the signal level and the size of the sound pressure level.

As a result, according to the second embodiment, (i) if the sound pressure level is set small by a user and the signal level is small in the band in the vicinity of the low-range limited band, (ii) if the sound pressure level is set large by a user and the signal level is small in the band in the vicinity of the low-range limited band, or (iii) if the sound pressure level is set small by a user and the signal level is large in the band in the vicinity of the low-range limited band, the frequency characteristic of the audio signal in the band in the vicinity of the low-range limited band is corrected on the basis of the size of the sound pressure level and the size of the signal level.

As a result, it is also possible to maintain a massive feeling of a sound reproduced from the speaker or high articulation of the sound, to thereby reproduce a high-quality sound at small volume.

The audio signal which is a processing target by the audio reproducing apparatus in the aforementioned embodiments may be an analog signal or digital signal. Moreover, the signal processing by the audio reproducing apparatus in the embodiments can be applied not only to the audio signal but also to a signal having the frequency characteristic, such as a signal including a motion-picture signal, a still-image signal, a communication signal some low-frequency signal, high-frequency signal, or the like.

Moreover, in the aforementioned embodiments, the audio reproducing apparatus, such as an AV receiver, provided with the frequency characteristic correcting device, such as an equalizer, is explained as one specific example of the audio reproducing apparatus. The present invention, however, can be also applied to an audio reproducing apparatus, such as an AV receiver, provided with a frequency characteristic correcting device, such as a graphic equalizer and a parametric equalizer. Moreover, it can be also applied not only to an audio reproducing apparatus for commercial use but also to an audio reproducing apparatus located in a large space, such as a concert hall and a shop, for business use.

The present invention is not limited to the aforementioned embodiment, and various changes may be made without departing from the essence or spirit of the invention which can be read from the claims and the entire specification. An audio reproducing apparatus and method, and a computer program, which involve such changes, are also intended to be within the technical scope of the present invention.

### INDUSTRIAL APPLICABILITY

The audio reproducing apparatus and method, and the computer program according to the present invention can be applied to an audio reproducing apparatus and method (or audio reproduction system) which perform signal processing on an audio signal. Moreover, they can be applied to the audio reproducing apparatus or the like which is mounted on various computer equipment for consumer use or for commercial use, or which can be connected to various computer equipment.

1-14. (canceled)

15. An audio reproducing apparatus for reproducing an audio signal during signal processing comprising:
a signal level detecting device for detecting a signal level of the audio signal;
a sound pressure level adjusting device for changing a sound pressure level which indicates an amplification factor of the audio signal;
a frequency characteristic correcting device for correcting at least a frequency characteristic of the audio signal on the basis of a correction amount; and
a controlling device for (i) determining the correction amount on the basis of the signal level and the sound pressure level and (ii) sequentially controlling said frequency characteristic correcting device at least to attenuate the frequency characteristic of the audio signal on the basis of the determined correction amount.

16. The audio reproducing apparatus according to claim 15, wherein
said audio reproducing apparatus further comprises a speaker for reproducing the audio signal, and
said frequency characteristic correcting device includes a second frequency characteristic correcting device for (i) attenuating the frequency characteristic of the audio level in which at least one of the signal level and the sound pressure level is relatively high, on the basis of the correction amount, in a low-range limited band in a reproduction frequency band of the speaker and (ii) boosting the frequency characteristic of the audio signal in which the one of the signal level and the sound pressure level is relatively low, on the basis of the correction amount, in the low range limited band, in order to correct a particular frequency band included in the frequency characteristic.

17. The audio reproducing apparatus according to claim 15, wherein
said audio reproducing apparatus further comprises a speaker for reproducing the audio signal, and
said frequency characteristic correcting device includes a second frequency characteristic correcting device for (i) attenuating the frequency characteristic of the audio signal in which at least one of the signal level and the sound pressure is relatively high, on the basis of the correction amount, in an antiresonance frequency band of the speaker and (ii) boosting the frequency characteristic of the audio signal in which the one of the signal level and the sound pressure is relatively low, on the basis of the correction amount, in the antiresonance frequency band, in order to correct a particular frequency band included in the frequency characteristic.

18. The audio reproducing apparatus according to claim 15, wherein
said audio reproducing apparatus further comprises a port type speaker for reproducing the audio signal, and
said frequency characteristic correcting device includes a second frequency characteristic correcting device for (i) attenuating the frequency characteristic of the audio signal in which at least one of the audio signal and the sound pressure is relatively high, on the basis of the correction amount, in a port resonance frequency band of the speaker and (ii) boosting the frequency characteristic of the audio signal in which the one of the signal level and the sound pressure level is relatively low, on the basis of the correction amount, in the port resonance frequency band, in order to correct a particular frequency band included in the frequency characteristic.

19. The audio reproducing apparatus according to claim 15, wherein
said audio reproducing apparatus further comprises a sealing type speaker for reproducing the audio signal, and
said frequency characteristic correcting device includes a second frequency characteristic correcting device for (i) attenuating the frequency characteristic of the audio signal in which at least one of the audio signal and the sound pressure is relatively high, on the basis of the correction amount, in a frequency band in which the displacement of the diaphragm is maximal and (ii) boosting the frequency characteristic of the audio signal in which the one of the signal level and the sound pressure level is relatively low, on the basis of the correction amount, in the frequency band in which displacement of the diaphragm is maximal, in order to correct a particular frequency band included in the frequency characteristic.

20. The audio reproducing apparatus according to claim 16, wherein said controlling device (i) controls said frequency characteristic correcting device to keep attenuating the frequency characteristic of the audio signal in which said audio reproducing apparatus further comprises a port type speaker for reproducing the audio signal, and
said frequency characteristic correcting device includes a second frequency characteristic correcting device for (i) attenuating the frequency characteristic of the audio signal in which at least one of the audio signal and the sound pressure is relatively high, on the basis of the correction amount, in a frequency band which is lower than the particular frequency band and (ii) controls said second frequency characteristic correcting device to keep boosting the frequency characteristic of the audio signal in which the one of the signal level and the sound pressure level is relatively low, on the basis of the correction amount, in the frequency band which is lower than the particular frequency band.

21. The audio reproducing apparatus according to claim 15, wherein said controlling device increases the correction amount in accordance with an extent that at least one of the signal level and the sound pressure level increases.

22. The audio reproducing apparatus according to claim 15, wherein said controlling device increases the correction amount if the signal level is greater than a first predetermined value and the sound pressure level is greater than a second predetermined value.

23. The audio reproducing apparatus according to claim 15, wherein said controlling device increases the correction amount in accordance with a first extent that the signal level increases and a second extent that the sound pressure level increases if the first extent is substantially equal to the second extent.

24. The audio reproducing apparatus according to claim 15, wherein said controlling device increases the correction amount in accordance with a first extent that the signal level increases and a second extent that the sound pressure level increases if the first extent is not equal to the second extent.

25. The audio reproducing apparatus according to claim 15, wherein said controlling device controls said frequency characteristic correcting device not to correct the frequency characteristic (i) if the signal level is smaller than a first predetermined value or (ii) if the sound pressure level is smaller than a second predetermined value.

26. The audio reproducing apparatus according to claim 15, wherein said controlling device controls said frequency characteristic correcting device (i) to attenuate the frequency characteristic of the audio signal on the basis of the correction amount if at least one of the signal level and the sound pressure level is relatively high, (ii) to boost the frequency characteristic of the audio signal on the basis of the correction amount if the one of the signal level and the sound pressure level is relatively low, and (iii) not to correct the frequency characteristic if the one of the signal level and the sound pressure level is relatively moderate.

27. An audio reproducing method in an audio reproducing apparatus for reproducing an audio signal during signal processing, said method comprising:
a signal level detecting process of detecting a signal level of the audio signal;
a sound pressure level adjusting process of changing a sound pressure level which indicates an amplification factor of the audio signal;
a frequency characteristic correcting process of correcting at least a frequency characteristic of the audio signal on the basis of a correction amount; and
a controlling process of (i) determining the correction amount on the basis of the signal level and the sound pressure level and (ii) sequentially controlling said frequency characteristic correcting process at least to attenuate the frequency characteristic of the audio signal on the basis of the determined correction amount.

28. A computer program embodied in a computer-readable medium for signal processing to control a computer provided in an audio reproducing apparatus, the computer program making the computer function as at least one portion of a signal level detecting device, a sound pressure level adjusting device, a frequency characteristic correcting device, and a controlling device,
said audio reproducing apparatus for reproducing an audio signal during signal processing, comprising:
said signal level detecting device for detecting a signal level of the audio signal;
said sound pressure level adjusting device for changing a sound pressure level which indicates an amplification factor of the audio signal;
said frequency characteristic correcting device for correcting at least a frequency characteristic of the audio signal on the basis of a correction amount; and
said controlling device for (i) determining the correction amount on the basis of the signal level and the sound pressure level and (ii) sequentially controlling said frequency characteristic correcting device at least to attenuate the frequency characteristic of the audio signal on the basis of the determined correction amount.

29. The audio reproducing apparatus according to claim 15, wherein said frequency characteristic correcting device includes a second frequency characteristic correcting device for (i) attenuating the frequency characteristic of the audio signal on the basis of the correction amount and (ii) boosting the frequency characteristic of the audio signal on the basis of the correction amount.
